(19) United States
(12) Patent Application Publication
(10) Pub. No.: US 2013/0043493 A1
(43) Pub. Date: Feb. 21, 2013

(54) LIGHT-EMITTING DIODE STRUCTURE

(71) Applicants: Richard Ta-Chung Wang, Kunshan City (CN); Shang-Bin Li, Kunshan City (CN); Zheng-Fei Xu, Kunshan City (CN); Jun Zou, Kunshan City (CN)

(72) Inventors: Richard Ta-Chung Wang, Kunshan City (CN); Shang-Bin Li, Kunshan City (CN); Zheng-Fei Xu, Kunshan City (CN); Jun Zou, Kunshan City (CN)

(73) Assignee: RICHARD, TA-CHUNG WANG, Kunshan City (CN)

(21) Appl. No.: 13/212,184

(22) Filed: Aug. 18, 2011

(51) Int. Cl. H01L 33/58

(52) U.S. Cl. 257/88; 257/E33.073

(57) ABSTRACT

A light-emitting diode (LED) structure includes a substrate, a plurality of LED chips, a first colloid, a second colloid, and a lens. The substrate is provided with at least one retaining section, and the LED chips are mounted on the substrate and covered by the first colloid. The second colloid is located to one side of the first colloid opposite to the substrate. The lens is provided with at least one catching section correspondingly engaged with the at least one retaining section, so that the lens is connected to the substrate to form a unitary body through engagement of the catching section with the retaining section and closes the LED chips, the first colloid and the second colloid in between the lens and the substrate. With these arrangements, the LED structure can have upgraded lighting efficiency and allows quick change of LED color temperature or LED beam angle.

### FIELD OF THE INVENTION

The present invention relates to a light-emitting diode (LED) structure, and more particularly to an LED structure including a substrate and a lens that can be quickly connected to each other through engagement of a retaining section and a catching section to enclose LED chips and colloid layers in between the substrate and the lens, so as to enable upgraded LED lighting efficiency and quick change of LED color temperature or LED beam angle.

### BACKGROUND OF THE INVENTION

Due to the rapid development in the recent light-emitting diode (LED) illuminating industry, the currently available LEDs can now have higher brightness and power, longer service life, lower power consumption, and faster response than the conventional energy-saving bulbs to thereby gradually replace the latter. Among others, high-power LEDs have been widely used on street lamps, scenery lighting, linear wall washer lights, interior illumination, and many other different lighting applications.

The constantly developing LED industry also enables the use of a multi-chip integrated LED module in a wide range of applications as a light source. A multi-chip integrated LED provides more unique advantages than a 1 W single-chip LED. And, following the further improved luminous efficacy of LED bare chips, the multi-chip integrated LED module can also be manufactured at largely reduced cost.

From the recent research and development in the LED industrial field, a high-power multi-chip integrated LED module has been introduced into the market, so that one single LED module can provide a high power ranged between 10 W and 100 W to overcome the problems of heat dissipation and light distribution as found with the conventional 5 W or higher power LED module.

According to an existing technique, a layer of fluorescent powder can be directly coated on LED bare chips for mixing the emitted color lights. However, a high-power multi-chip LED module has a thermal power density much higher than that of a single-chip LED. Meanwhile, the temperature at a central hot spot of the LED structure would adversely affect the lighting efficiency and the life of the fluorescent powder coated on the chips. Therefore, the fluorescent powder should be coated at a position far away from the LED bare chips. Another technique has been developed to overcome the above problem by using a light guide plate to guide out the light produced by the LED bare chips and reflect the light onto a light emitting surface with the fluorescent powder layer. Although this technique enables lowered temperature at the fluorescent powder layer, the luminous efficacy of the whole LED module is reduced and the manufacturing cost is increased, and LED lamps produced with this technique also have reduced lighting efficiency.

In brief, the conventional LED structures have the following disadvantages: (1) poor lighting efficiency; and (2) increased manufacturing cost.

It is therefore tried by the inventor to develop an improved LED structure to overcome the disadvantages in the conventional LED structures.

### SUMMARY OF THE INVENTION

A primary object of the present invention is to provide an LED structure that provides upgraded light efficiency.

Another object of the present invention is to provide an LED structure that enables quick change of LED color temperature or LED beam angle.

A further object of the present invention is to provide an LED structure that eliminates the problem of luminous flux attenuation caused by fluorescent powder constantly working under high temperature.

To achieve the above and other objects, the LED structure according to the present invention includes a substrate having a recess formed on one side thereof and at least one retaining section provided on along a peripheral wall thereof; a plurality of LED chips arranged in the recess of the substrate; a first colloid located in the recess of the substrate to cover the LED chips; a second colloid located to one side of the first colloid opposite to the substrate; and a lens having at least one catching section provided on along a peripheral wall thereof for correspondingly engaging with the at least one retaining section on the substrate. The lens is connected to the substrate to form a unitary body through engagement of the catching section with the retaining section, and closes the LED chips, the first colloid and the second colloid in between the lens and the substrate. With the second colloid located between the lens and the first colloid, and the catching section detachably engaged with the retaining section, the LED structure can provide upgraded light efficiency and enables quick change of LED color temperature or LED beam angle.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of an LED structure according to a first preferred embodiment of the present invention;

FIG. 2 is an assembled view of FIG. 1;

FIG. 3 is a sectional view of FIG. 2;

FIG. 4 an exploded perspective view of an LED structure according to a second preferred embodiment of the present invention;

FIG. 5 is an assembled view of FIG. 4;

FIG. 6 is a sectional view of an LED structure according to a third preferred embodiment of the present invention;

FIG. 7 is a sectional view of an LED structure according to a fourth preferred embodiment of the present invention;

FIG. 8 is a sectional view of an LED structure according to a fifth preferred embodiment of the present invention;

FIG. 9 is a sectional view of an LED structure according to a sixth preferred embodiment of the present invention; and

FIG. 10 is a sectional view of an LED structure according to a seventh preferred embodiment of the present invention.

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

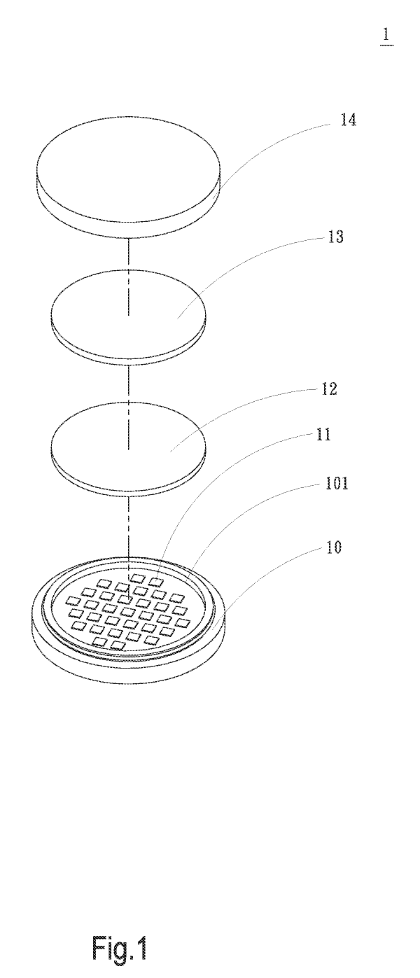

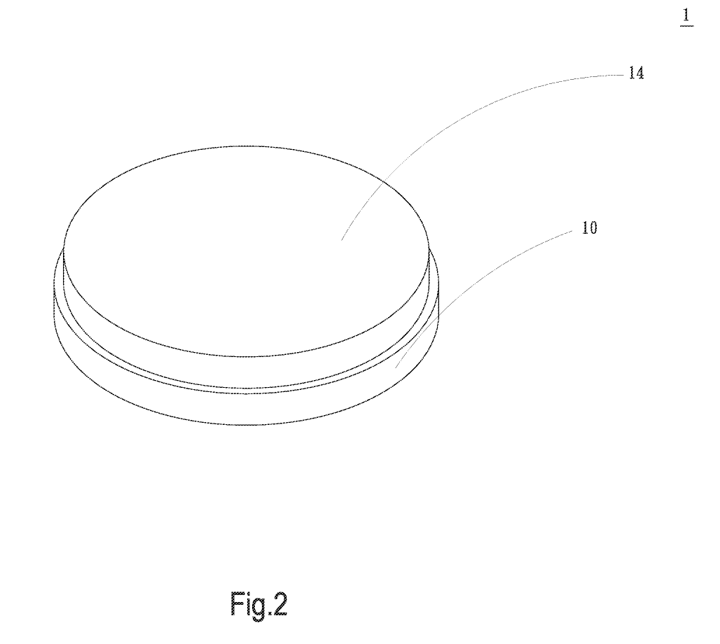

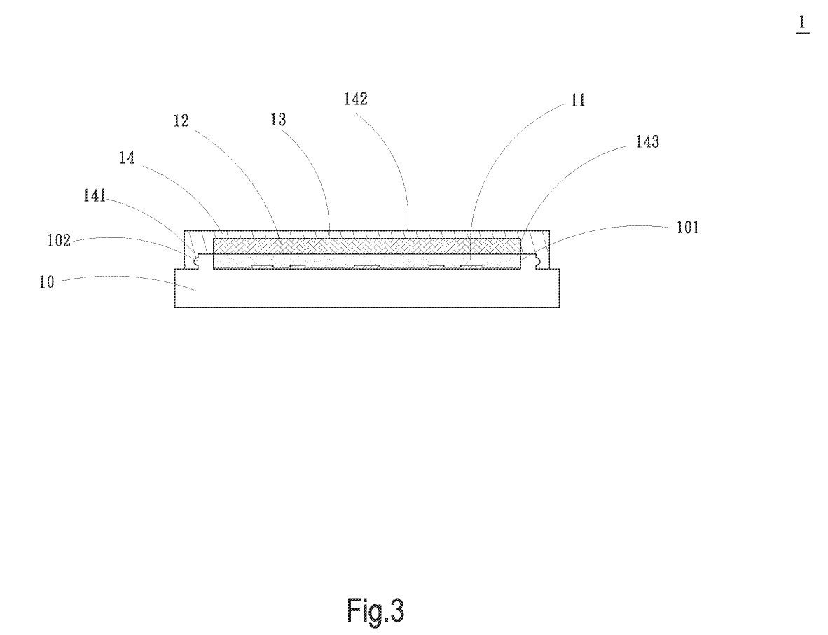

Please refer to FIGS. 1 and 2 that are exploded and assembled perspective views, respectively, of an LED structure 1 according to a first preferred embodiment of the present invention, and to FIG. 3 that is a sectional view of FIG. 2. As shown, the LED structure 1 in the first preferred embodiment includes a substrate 10, a plurality of light-emitting diode (LED) chips 11, a first colloid 12, a second colloid 13, and a lens 14.

The substrate 10 is formed on one side with a recess 101, and is provided on along a peripheral wall with at least one retaining section 102. In the illustrated first embodiment, the retaining section 102 is extended along the peripheral wall of the substrate 10. The LED chips 11 are arranged in the recess 101. The first colloid 12 is located in the recess 101 to cover the LED chips 11. The second colloid 13 is located to one side of the first colloid 12 opposite to the substrate 10. The lens 14 is formed on along a peripheral wall at a predetermined position with at least one catching section 141 for correspondingly engaging with the at least one retaining section 102 on the substrate 10, so that the lens 14 is connected to the substrate 10 to form a unitary body through engagement of the catching section 141 with the retaining section 102 and closes the LED chips 11, the first colloid 12, and the second colloid 13 in between the lens 14 and the substrate 10.

The substrate 10 can be formed of a copper material, an aluminum material, a ceramic material, a graphite material, a silicon material, or a printed circuit board. The LED chips 11 are arranged in the recess 101 of the substrate 10 and include LED bare chips of different wavelengths. For example, the LED bare chips 11 may include a plurality of InGaN or GaN LED bare chips and a plurality of AlGaInP LED bare chips, so that a spectrum having at least two peak wavelengths of 450-460 nm and 620-660 nm can be obtained when a bias voltage is applied to the LED chips 11.

In the illustrated first embodiment, the LED chips 11 used are red bare chips and blue bare chips without being limited thereto. The red bare chips are arranged at a central area of the substrate 10 while the blue bare chips are arranged around the red bare chips to locate outside the latter. Further, the LED chips 11 are in tight contact with the substrate 10 through the surface-mount technology (SMT), so that the LED chips 11 and the substrate 10 are bound together to form a unitary body. And, the retaining section 102 on the peripheral wall of the substrate 10 is engaged with the catching section 141 on the lens 14.

The lens 14 can be made of a material selected from the group consisting of silicones, silicone resins, optical polycarbonates (PC), glass, and acrylic resins. One side of the lens 14 opposite to the substrate 10 is a light emitting side 142. Depending on the configuration of the light emitting side 142, the lens 14 can be a plane lens, a convex lens, a concave lens, a meniscus lens, a wave lens, or a lens array without being limited thereto. In the illustrated first embodiment, the lens 14 is a plane lens. The lens 14 is formed on one side facing toward the substrate 10 with a recess 143, in which the second colloid 13 is fixedly set. The second colloid 13 is molded using a die to have a shape corresponding to that of the recess 143, so as to be tightly fitted in the recess 143.

The second colloid 13 is a silicone material having fluorescent powder mixed therein. In the illustrated embodiment, the second colloid 13 has a thickness ranged between 0.5 mm and 1 mm, and the fluorescent powder mixed therein can be an aluminate or a silicate or any other chemical material capable of producing fluorescent effect; the spectrum used in the illustrated first preferred embodiment may range from 450 nm to 460 nm and from 620 nm to 660 nm; and a shortest distance between the second colloid 13 and the LED chips 11 is larger than a shortest distance between any two LED chips 11 that have different wavelengths.

The second colloid 13 is fixedly set in the recess 143 of the lens 14. When the lens 14 is connected to the substrate 10 through engagement of the catching section 141 with the retaining section 102, the first colloid 12 is located between the second colloid 13 and the substrate 10 to cover the LED chips 11. The first colloid 12 has a refractive index smaller than 1.43, and can be a transparent silicone material or a cooling liquid. In the case of using a transparent silicone material as the first colloid 12, the LED chips 11 are completely covered by the silicone material. Due to the inherent characteristics thereof, the transparent silicone material can effectively maintain its high transmittance and transparency to the visible light and therefore minimizes changes of refractive index along the optical path to advantageously increase an overall lighting efficiency of the LED chips 11, such as to increase the LED structure's efficiency by 10%-20%. On the other hand, in the case of using a cooling liquid as the first colloid 12, the LED chips 11 can also be completely covered. The cooling liquid can enhance the overall heat dissipation effect of the LED structure to effectively lower the temperature of the LED chips 11.

With the above arrangements, the second colloid 13 serving as a fluorescent powder layer in the LED structure of the present invention is located farther from the LED chips 11. Further, since the lens 14 and the substrate 10 are connected to each other through engagement of the catching section 141 with the retaining section 102, the lens 14 or the second colloid 13 are changeable according to the requirement for LED color temperature or LED beam angle in order to achieve enhanced lighting efficiency and quick change of LED color temperature or LED beam angle.

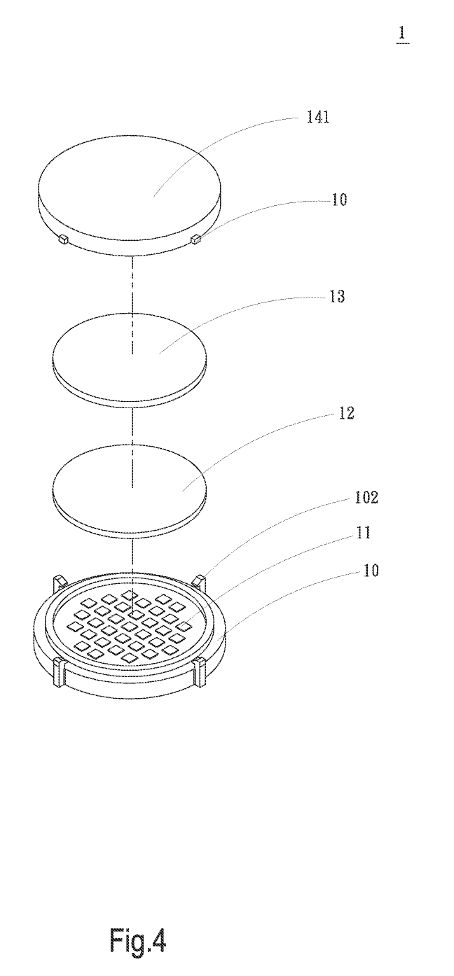

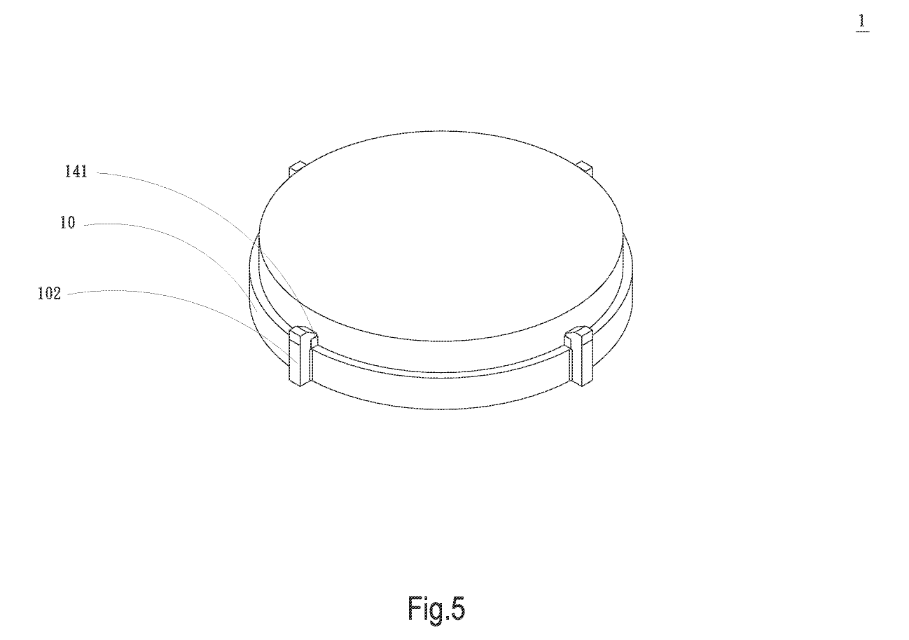

Please refer to FIGS. 4 and 5 that are exploded and assembled perspective views, respectively, of an LED structure according to a second preferred embodiment of the present invention. As shown, the second embodiment is generally structurally similar to the first embodiment, except that, in the second embodiment, the substrate 10 is provided on two or four positions along the peripheral wall thereof with a retaining section 102 each, and the lens 14 is provided on two or four positions along the peripheral wall thereof with a catching section 141 each to correspond to the retaining sections 102. In the illustrated second embodiment, there are shown four retaining sections 102 and four catching sections 141. And, in the second preferred embodiment, the retaining sections 102 are respectively a hooking member and the catching sections 141 are respectively a protrusion corresponding to the hooking member, such that the lens 14 is connected to the substrate 10 to form a unitary body through engagement of the catching section 141 with the retaining sections 102 and closes the LED chips 11, the first colloid 12, and the second colloid 13 in between the lens 14 and the substrate 10.

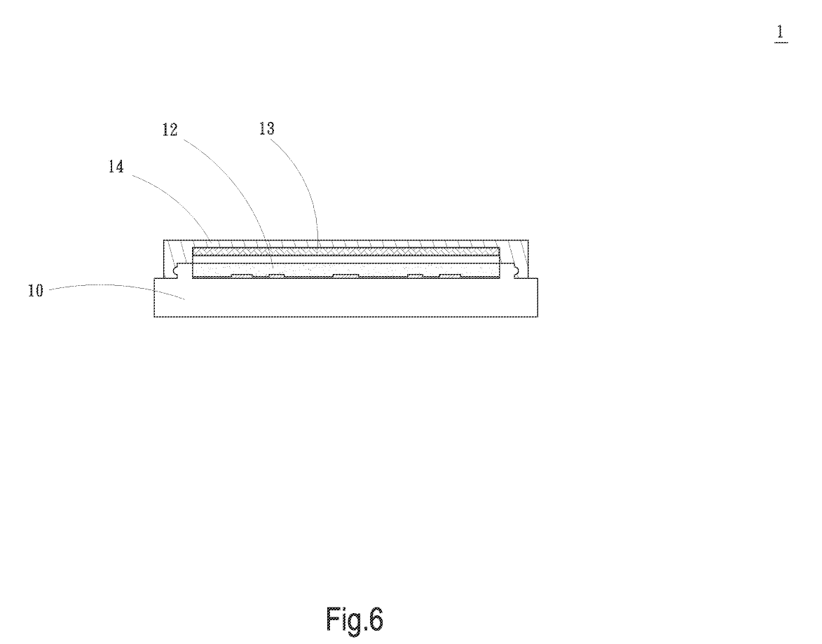

FIG. 6 is a sectional view of an LED structure according to a third preferred embodiment of the present invention. As shown, the third embodiment is generally structurally similar to the first embodiment, except that, in the third embodiment, the second colloid 13 located to one side of the first colloid 12 opposite to the substrate 10 and serving as a fluorescent powder layer is coated on the lens 14. With these arrangements, the LED structure 1 according to the third embodiment also allows change of the lens 14 or the second colloid 13 according to the requirement for LED color temperature or LED beam angle and achieves enhanced lighting efficiency and quick change of LED color temperature or LED beam angle.

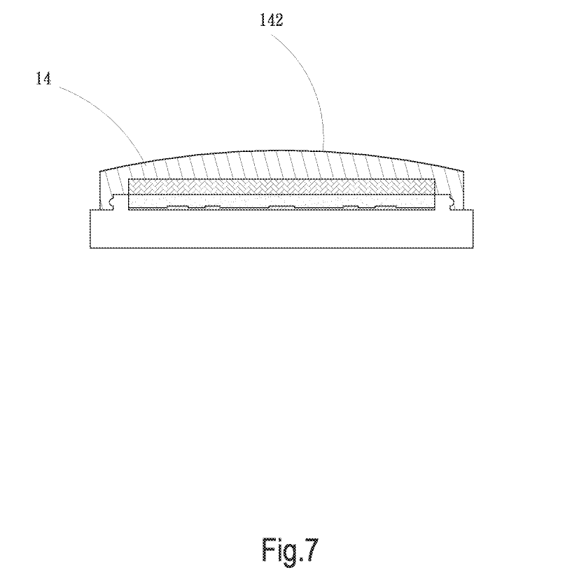

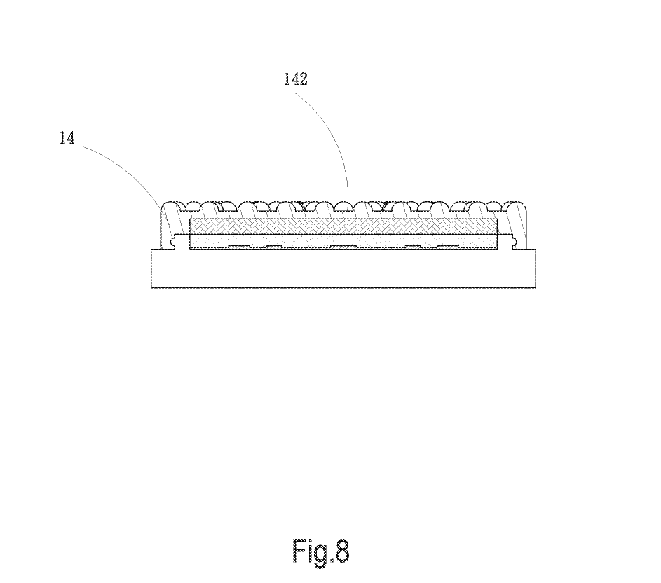

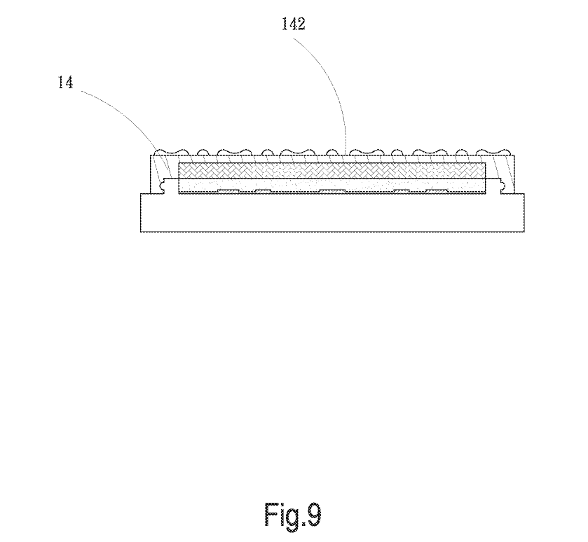

FIGS. 7, 8 and 9 are sectional views of LED structures according to a fourth, a fifth and a sixth preferred embodiment of the present invention, respectively. As shown, the fourth, fifth and sixth embodiments are generally structurally similar to the first preferred embodiment, except that the lenses 14 in these three embodiments respectively have a light emitting side 142 being configured according to actual requirement and different from the plane lens in the first embodiment. In FIG. 7, the lens 14 is a convex lens, which enables increased light extraction and enhanced luminous efficacy. And, by adjusting the curvature of the lens 14 or designing a light emitting side 142 having a non-spherical surface, the convex lens 14 can have a beam angle ranged between 140 degrees and 30 degrees. In FIG. 8, the lens 14 is a lens array including a plurality of molded hemispherical lens arrayed on the light emitting side 142. The lens 14 in the form of a lens array also enables increased light extraction and enhanced luminous efficacy, as well as a beam angle ranged between 140 degrees and 10 degrees. In FIG. 9, the lens 14 is a lens array including a plurality of hemispherical lenses and a plurality of concave spherical lenses alternately arrayed on the light emitting side 142 to achieve two or more light distribution surfaces.

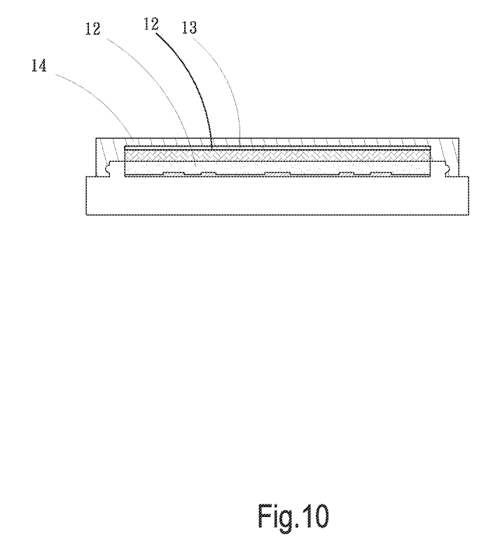

Please refer to FIG. 10 that is a sectional view of an LED structure according to a seventh preferred embodiment of the present invention. As shown, the seventh embodiment is generally structurally similar to the first preferred embodiment, except that, in the seventh embodiment, an additional layer of the first colloid 12 is further provided between the lens 14 and the second colloid 13, so as to achieve the effect of filling and sealing a space, if any, between the lens 14 and the second colloid 13.

In brief, the present invention provides an LED structure having the following advantages: (1) providing upgraded lighting efficiency; (2) allowing quick change of LED color temperature or LED beam angle; (3) eliminating luminous flux attenuation; and (4) reduced manufacturing cost.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light-emitting diode (LED) structure, comprising:
a substrate having a recess formed on one side thereof and at least one retaining section provided on along a peripheral wall thereof;
a plurality of LED chips being arranged in the recess of the substrate;
a first colloid being located in the recess of the substrate to cover the LED chips;
a second colloid being located to one side of the first colloid opposite to the substrate; and
a lens being provided on along a peripheral wall with at least one catching section for correspondingly engaging with the at least one retaining section on the substrate.

2. The LED structure as claimed in claim 1, further comprising an additional layer of the first colloid being filled between the lens and the second colloid.

3. The LED structure as claimed in claim 2, wherein the first colloid is selected from the group consisting of a transparent silicone material and a cooling liquid.

4. The LED structure as claimed in claim 1, wherein the second colloid is a silicone material mixed with fluorescent powder.

5. The LED structure as claimed in claim 1, wherein one side of the lens opposite to the substrate is a light emitting side.

6. The LED structure as claimed in claim 5, wherein the lens is selected from the group consisting of a plane lens, a convex lens, a concave lens, a meniscus lens, a wave lens, and a lens array.

7. The LED structure as claimed in claim 6, wherein the lens array includes a plurality of molded hemispherical lenses arrayed on the light emitting side of the lens.

8. The LED structure as claimed in claim 6, wherein the lens array includes a plurality of hemispherical lenses and a plurality of concave spherical lenses alternately arrayed on the light emitting side of the lens.

9. The LED structure as claimed in claim 1, wherein the lens is made of a material selected from the group consisting of silicones, silicone resins, optical polycarbonates, glass, and acrylic resins.

10. The LED structure as claimed in claim 1, wherein the lens is formed on one side facing toward the substrate with a recess, and the second colloid being fixedly set in the recess of the lens.
